(19) United States
(12) Patent Application Publication
(10) Pub. No.: US 2015/0023084 A1
(43) Pub. Date: Jan. 22, 2015

(54) SEMICONDUCTOR MODULE

(71) Applicant: FUJI ELECTRIC CO., LTD., KAWASAKI-SHI (JP)

(72) Inventor: Tadahiko SATO, Matsumoto-shi (JP)

(21) Appl. No.: 14/508,452

(22) Filed: Oct. 7, 2014

Related U.S. Application Data
(63) Continuation of application No. PCT/JP2013/071061, filed on Aug. 2, 2013.

(30) Foreign Application Priority Data
Sep. 20, 2012 (JP) 2012-207645

(51) Int. Cl. H02M 7/5387; H01L 25/07

(52) U.S. Cl. CPC H02M 7/5387; H01L 25/07
USPC 363/132

(57) ABSTRACT

A semiconductor module includes a plurality of power semiconductor elements forming upper arms and lower arms of a plurality of sets of half bridge circuits; a plurality of control circuits on/off driving each power semiconductor element having a control terminal of the plurality of power semiconductor elements; and a power supply terminal and a plurality of control terminals, connected to a plurality of respective external connection control terminals. Low potential side electrodes of the power semiconductor elements forming the respective upper arms of the plurality of sets of half bridge circuits and high potential side electrodes of the power semiconductor elements forming the respective lower arms of the plurality of sets of half bridge circuits are individually connected to a plurality of respective external connection output terminals.

### CROSS-REFERENCE TO RELATED APPLICATION

The present application is a continuation application of PCT International Application No. PCT/JP2013/071061 filed Aug. 2, 2013, and claims priority from Japanese Application No. 2012-207645 filed Sep. 20, 2012.

### TECHNICAL FIELD

The present invention relates to a semiconductor module including a plurality of power semiconductor elements which forms upper arms and lower arms in a plurality of sets of half bridge circuits.

### BACKGROUND ART

A semiconductor module including a plurality of power semiconductor elements which forms the upper arms and lower arms in a plurality of sets of half bridge circuits is used as a component in the output stage of an inverter device which drives a load such as a motor. FIG. 6 is a diagram showing an outline configuration of a main portion of a semiconductor module IPM used in an inverter device which drives a three-phase motor M, wherein Q1 and Q2 to Q6 are six switching elements forming three sets of half bridge circuits. Also, D1 and D2 to D6 are free wheeling diodes connected in reverse parallel to the respective switching elements Q1 and Q2 to Q6.

Herein, the three sets of half bridge circuits are configured in such a way that the switching elements Q1, Q2, and Q3, forming upper arms, which are commonly connected to a power supply terminal P to which a direct current voltage is applied, and the switching elements Q4, Q5, and Q6 forming lower arms, are respectively connected in series in pairs. In each of the half bridge circuits, the connection point of the switching element Q1 (Q2, Q3) forming the upper arm and the switching element Q4 (Q5, Q6) forming the lower arm is used as an output terminal L1 (L2, L3) which supplies U-phase (V-phase, W-phase) power to the three-phase motor M.

Also, the other terminals of the switching elements Q4, Q5, and Q6 forming the lower arms are connected to respective ground side terminals N1, N2, and N3. The ground side terminals N1, N2, and N3 are grounded via, for example, shunt resistors R1, R2, and R3. The switching elements Q1 and Q2 to Q6 are power semiconductor elements each being formed of an IGBT or MOS-FET having a control electrode (gate electrode). A semiconductor module IPM of this kind of configuration is introduced in detail in, for example, PTL 1.

FIG. 7 shows a layout structure example of the heretofore described semiconductor module IPM. As shown in FIG. 7, the heretofore known semiconductor module IPM includes an insulating substrate 2 substantially in the central portion of a terminal case forming a rectangular module main body. Further, in the semiconductor module IPM, an aligned set of the switching elements Q1 and Q2 to Q6 and an aligned set of the free wheeling diodes D1 and D2 to D6 are arrayed parallel to each other on the insulating substrate 2. In FIG. 7, numeral 3 are conductors, and numerals 4 and 5 are a plurality of lead frames (LF) forming external connection control terminals. The conductors 3 are formed of lead frames (3 and 3h), which can be used as external connection control terminals, and a plurality of wiring patterns (3a to 3g) on an aluminum insulating substrate.

Also, the semiconductor module IPM includes high side control circuits IC1, IC2, and IC3 which individually on/off drive the respective switching elements Q1, Q2, and Q3 forming the upper arms. Furthermore, the semiconductor module IPM includes a low side control circuit 104 which on/off drives he respective switching elements Q4, Q5, and Q6 forming the lower arms. The control circuits IC1, IC2, IC3, and IC4 are arrayed, aligned in a line, parallel to an array direction of the switching elements Q1 and Q2 to Q6. The array structure of the switching elements Q1 and Q2 to Q6, free wheeling diodes D1 and D2 to D6, and control circuits IC1, IC2, IC3, and IC4 is determined by considering that no unsatisfactory current loop is formed in the semiconductor module IPM and that a smallest current loop is formed.

The semiconductor module IPM of the configuration shown in FIG. 6 is obtained by mutually connecting the plurality of wiring patterns 3 forming the conductors, the switching elements Q1 and Q2 to Q6, the free wheeling diodes D1 and D2 to D6, and the control circuits IC1, IC2, and 103 using connecting wires which are wires such as gold wires. Also, the external connection output terminals led out to the external from the module main body are arrayed in the order of, for example, the power supply terminal P, output terminal L1, L2, and L3, and ground side terminal N1, N2, and N3 along one long edge of the module main body. Also, external connection control terminals for inputting and outputting control signals or the like into and from the control circuits IC1, IC2, IC3, and IC4 are arrayed along the other long edge of the module main body. A semiconductor element structure which forms the semiconductor module of the heretofore described layout structure is introduced in detail in, for example, PTL 2.

### CITATION LIST

### Patent Literature

PTL 1: Japanese Patent No. 3394377

PTL 2: Japanese Patent No. 3941266

### SUMMARY OF INVENTION

### Technical Problem

However, in the semiconductor module of the heretofore described configuration, the upper arm side switching element Q1, Q2, Q3 and the lower arm side switching element Q4, Q5, Q6 are internally connected for each set forming the half bridge circuits, and that the connection points of the upper arm side switching elements Q1, Q2, and Q3 and the respective lower arm side switching elements Q4, Q5, and Q6 are led out to the external directly as the external connection output terminals L1, L2, and L3, respectively. Because of this, it is impossible to form, for example, a double forward converter or an interleaved boost converter using the semiconductor module. Specifically, it is not possible to interpose, for example, a coil or an inductance between the upper arm side switching element Q1 (Q2, Q3) and the lower arm side switching element Q4 (Q5, Q6). Consequently, the application of the semiconductor module of the heretofore described configuration as a driver circuit for the three-phase motor M, or the like, is limited.

The invention has been made with reference to these kinds of circumstances, and has an object of providing a semiconductor module which includes a plurality of power semiconductor elements forming the upper arms and lower arms in a plurality of sets of half bridge circuits, and particularly, which can be applied to various applications without changing the layout structure of the semiconductor module.

### Means to Solve the Problem

A semiconductor module according to the invention has mounted thereon a plurality of power semiconductor elements forming upper arms and lower arms of a plurality of sets of half bridge circuits, and a plurality of control circuits on/off driving each power semiconductor elements having a control terminal of the plurality of power semiconductor elements, and a power supply terminal and a plurality of control terminals of each of the control circuits are connected to a plurality of respective external connection control terminals.

Particularly, in order to achieve the heretofore described object, the semiconductor module according to the invention, low potential side electrodes of the power semiconductor elements forming the respective upper arms of the plurality of sets of half bridge circuits and high potential side electrodes of the power semiconductor elements forming the respective lower arms of the plurality of sets of half bridge circuits are individually connected to a plurality of respective external connection output terminals.

Preferably, the power semiconductor elements are switching elements, each being formed of, for example, an IGBT or MOS-FET having a control electrode, and diodes, each being paired with each respective switching element. Further, the semiconductor module has a structure wherein the high potential side electrodes of the power semiconductor elements forming the respective upper arms of the plurality of sets of half bridge circuits are mounted, commonly connected to each other, on an insulating substrate, while the power semiconductor elements forming the respective lower arms of the plurality of sets of half bridge circuits are mounted, separated from one another, on the insulating substrate.

Preferably, the power semiconductor elements forming the respective upper arms of the plurality of sets of half bridge circuits are disposed to align parallel to a long edge of a rectangular module main body on which the plurality of external connection output terminals are arrayed. Also, the power semiconductor elements forming the respective lower arms of the plurality of sets of half bridge circuits are disposed to align parallel to an array direction of the power semiconductor elements forming the respective upper arms.

Further, the switching elements and the diodes are alternately arrayed on each of the upper arm side and lower arm side of the plurality of sets of half bridge circuits. After that, it is preferable that the external connection output terminals individually connected to the low potential side electrodes of the power semiconductor elements forming the respective upper arms of the plurality of sets of half bridge circuits, and the external connection output terminals individually connected to the high potential side electrodes of the power semiconductor elements forming the respective lower arms of the plurality of sets of half bridge circuits, are disposed adjacent to each other in pairs with one pair for each of the plurality of sets of half bridge circuits.

### Advantageous Effects of Invention

In the semiconductor module of the heretofore described configuration, the low potential side electrodes of the upper arm side power semiconductor elements and the high potential side electrodes of the lower arm side power semiconductor elements are individually connected to the plurality of respective external connection output terminals. Hence, it is easy, for example, to interpose a coil or an inductance between the low potential side and high potential side electrodes via the external connection output terminal. Consequently, it is possible to easily form, for example, a double forward converter or an interleaved boost converter.

Also, when forming a semiconductor module for exclusive use in the previously described inverter device which drives the three-phase motor, it is possible to respond simply by, for example, mutually connecting the low potential side electrodes of the upper arm side power semiconductor elements and the high potential side electrodes of the lower arm side power semiconductor elements, using connecting wires which are wires such as gold wires, inside the semiconductor module, and it is possible to form the semiconductor module without changing the layout structure thereof. Consequently, it is possible to form a semiconductor module, the applications of which are provided with versatility, and the semiconductor module has immense practical advantages.

### BRIEF DESCRIPTION OF DRAWINGS

FIG. 1 is an outline configuration diagram of a semiconductor module according to one embodiment of the invention.

FIG. 2 is a diagram showing a layout structure of the semiconductor module shown in FIG. 1.

FIG. 3 is a diagram showing a configuration of an interleaved boost converter using the semiconductor module shown in FIG. 1.

FIG. 4 is a diagram showing a configuration when the semiconductor module according to the invention is modified and used for driving a three-phase motor.

FIG. 5 is a diagram showing a modification of an internal wire connection in the semiconductor module layout structure which forms a semiconductor module for driving the three-phase motor shown in FIG. 4.

FIG. 6 is a diagram showing a configuration of a heretofore known common semiconductor module used in an inverter device which drives a three-phase motor.

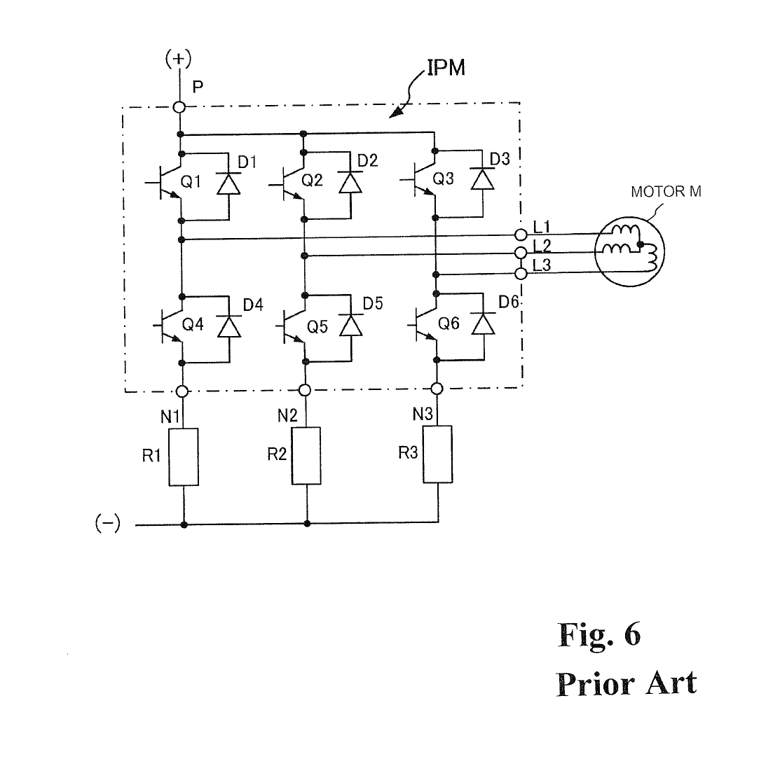

FIG. 7 is a diagram showing a layout structure of the heretofore known semiconductor module.

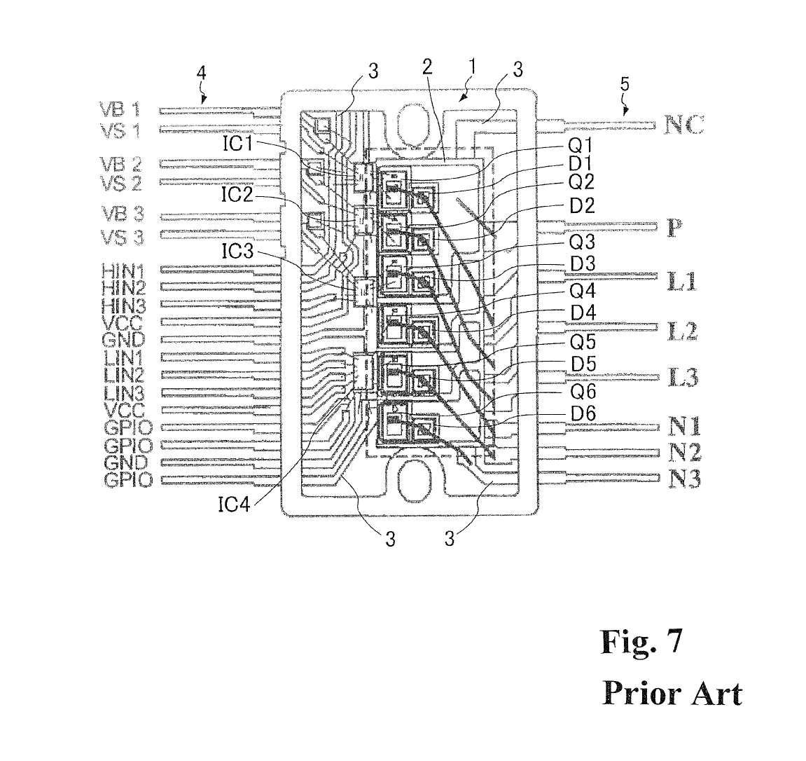

### DESCRIPTION OF EMBODIMENTS

Hereafter, a description will be given, referring to the drawings, of a semiconductor module according to one embodiment of the invention.

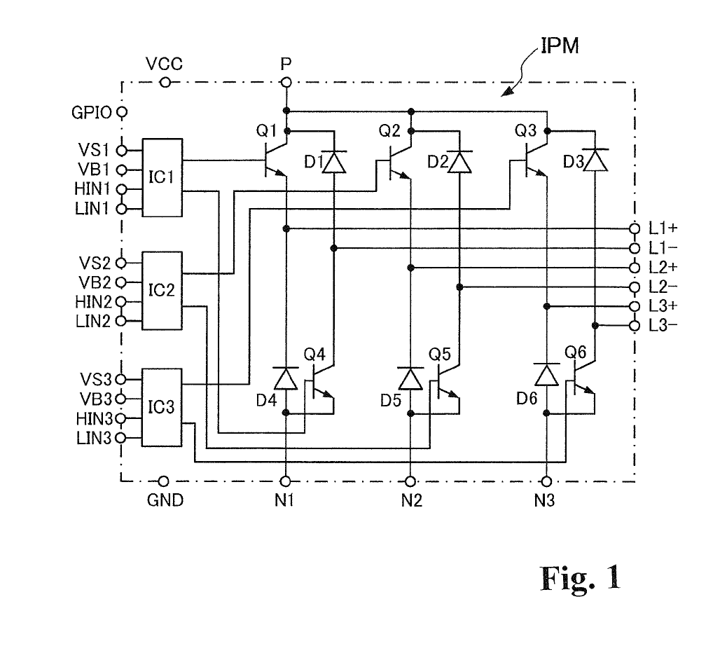

FIG. 1 is an outline diagram of a semiconductor module IPM according to the embodiment. The semiconductor module IPM shown in FIG. 1 includes six switching elements Q1 and Q2 to Q6, and six free wheeling diodes D1 and D2 to D6, which form three sets of half bridge circuits. Also, the semiconductor module IPM includes three control circuits IC1, IC2, and IC3 which on/off drive the respective switching elements Q1 and Q2 to Q6. The semiconductor module IPM forming the three sets of half bridge circuits will be described here, but may form two or four or more sets of half bridge circuits.

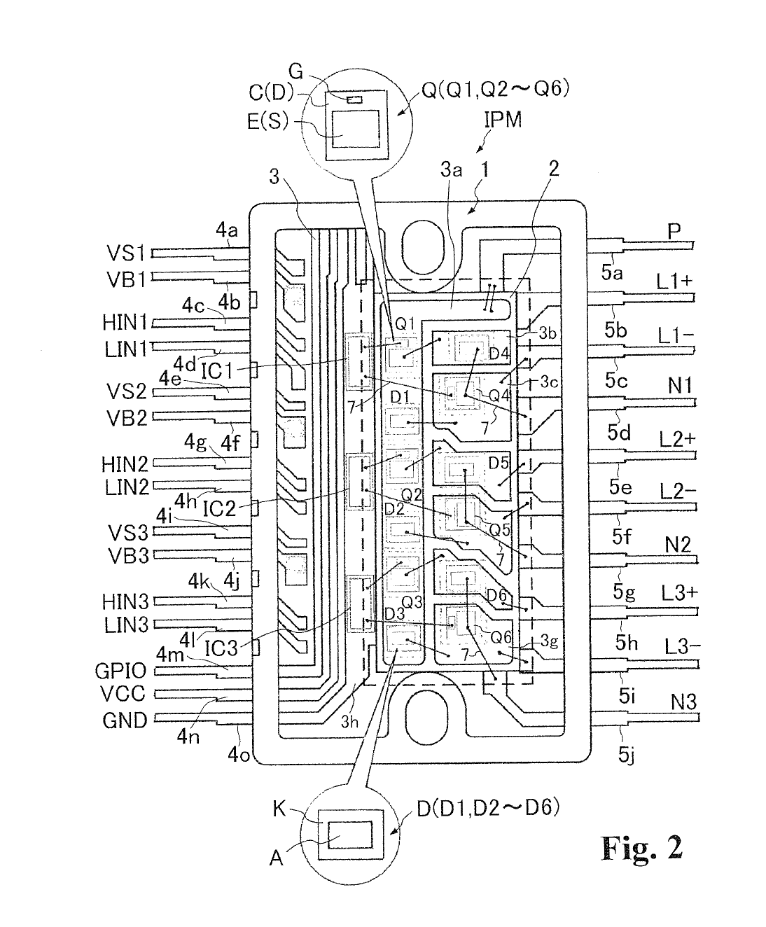

FIG. 2 shows a layout structure of the semiconductor module IPM shown in FIG. 1. In FIG. 2, reference 2 is an insulating substrate, provided substantially in the central portion of a rectangular module main body 1, which forms the substrate of the semiconductor module IPM. The insulating substrate 2 is formed of, for example, an insulating metal substrate wherein metal conductor layers are formed on a ceramic substrate. Also, lead frames (3 and 3h) operating also as external connection control terminals and a plurality of wiring patterns (3a to 3g) on an aluminum insulating substrate are formed on the insulating substrate 2 by lithography or the like. Further, the six switching elements Q1 and Q2 to Q6 which are a plurality of power semiconductor elements and the six free wheeling diodes D1 and D2 to D6 are mounted, and the three control circuits IC1, IC2, and IC3 are mounted on the insulating substrate 2.

Herein, the six switching elements Q1 and Q2 to Q6, which are formed of, for example, IGBTs, are basically connected in series by twos to form three sets of half bridge circuits. Also, the six free wheeling diodes D1 and D2 to D6 are basically connected in reverse parallel to the respective switching elements Q1 and Q2 to Q6, thus making the role of forming a free wheeling current path.

Also, a plurality (for example, 15) of lead frames (LF) 4a and 4b to 4o forming a plurality of external connection control terminals is disposed in parallel on one long edge of the module main body 1. Also, a plurality (for example, ten) of lead frames (LF) 5a and 5b to 5j forming a plurality of external connection output terminals is disposed in parallel on the other long edge of the module main body 1. The lead frames (LF) 4a and 4b to 4o assume the role of inputting and outputting control signals or the like into and from the control circuits IC1, IC2, and IC3. Also, the lead frames (LF) 5a and 5b to 5j assume the role of supplying currents, output one by each of the switching elements Q1 and Q2 to Q6, to the external.

Herein, in the semiconductor module IPM according to the invention, as shown in FIG. 1 showing an outline configuration of the semiconductor module IPM and FIG. 2 showing a layout structure of the semiconductor module IPM, sources, which are the low potential side electrodes of the switching elements (IGBTs) Q1, Q2, and Q3 of the upper arms of a plurality (for example, three) of sets of half bridge circuits, and drains, which are the high potential side electrodes of the power semiconductor elements of the switching elements (IGBTs) Q4, Q5, and Q6 forming the respective lower arms of the plurality (for example, three) of sets of half bridge circuits, are individually connected to the respective lead frames 5a and 5b to 5j which are the plurality of external connection output terminals.

Also, as shown in FIG. 1, the cathodes of the free wheeling diodes D4, D5, and D6 provided on the lower arm sides of the half bride circuits are connected in series to the respective sources which are the low potential side electrodes of the upper arm side switching elements Q1, Q2, and Q3. Further, the anodes of the free wheeling diodes D4, D5, and D6 are connected to the sources which are the low potential side electrodes of the lower arm side switching elements Q4, Q5, and Q6.

Also, the cathodes of the free wheeling diodes D1, D2, and D3 provided on the upper arm sides are commonly connected to the respective drains which are the high potential side electrodes of the upper arm side switching elements Q1, Q2, and Q3. Further, the anodes of the free wheeling diodes D1, D2, and D3 are connected in series to the respective drains which are the high potential side electrodes of the lower arm side switching elements (IGBTs) Q4, Q5, and Q6.

That is, the upper arm side switching elements Q1, Q2, and Q3 and the lower arm side free wheeling diodes D4, D5, and D6 are connected in series, respectively, and the lower arm side switching elements Q4, Q5, and Q6 and the upper arm side free wheeling diodes D1, D2, and D3 are connected in series, respectively. Further, six series circuits, each formed of the switching element Q and free wheeling diode D, are provided in parallel.

Further, the connection points of the switching elements Q and free wheeling diodes D in the respective series circuits are individually connected to the six respective independent lead frames 5 (5b, 5c, 5e, 5f, 5h, and 5i), and are led out to the external as external connection output terminals L1+, L1−, L2+, L2−, L3+, and L3−. Also, the drains which are the high potential side electrodes of the upper arm side switching elements (IGBTs) Q1, Q2, and Q3 and the cathodes of the upper arm side free wheeling diodes D1, D2, and D3 are commonly connected to each other, then connected to one (5a) of the lead frames 5, and are led out to the external as a power supply terminal P. Furthermore, the sources which are the low potential side electrodes of the lower side switching elements Q4, Q5, and Q6 are individually connected to the other respective lead frames 5 (5d, 5g, and 5j), of the ten lead frames 5, and are led out to the external as external connection output terminals N1, N2, and N3.

Herein, the layout structure of the switching elements Q1 and Q2 to Q6 and free wheeling diodes D1 and D2 to D6 is determined, as shown in FIG. 2, taking into account this kind of relation of connection of the switching elements Q1, Q2, and Q3 and free wheeling diodes D1, D2, and D3 so that no unsatisfactory current loop is formed in the semiconductor module IPM and that a smallest current loop is formed.

That is, the upper arm side switching elements Q1, Q2, and Q3 and free wheeling diodes D1, D2, and D3 are alternately disposed on and along the conductor layer 3a disposed parallel to the long edges of the module main body 1 on the insulating substrate 2. Specifically, the switching element Q1, the free wheeling diode D1, the switching element Q2, the free wheeling diode D2, the switching element Q3, and the free wheeling diode D3 are disposed in this order from the upper side in FIG. 2.

Each switching element (IGBT) Q has an element structure wherein an emitter region (that is, an emitter electrode) E is formed on a collector region C via an unshown insulating layer, and a gate electrode G is led out to a side portion of the emitter electrode E, in outline, as shown partially enlarged in FIG. 2. Also, each free wheeling diode D has an element structure wherein an anode region (that is, an anode electrode) A is formed on a cathode region K via an unshown insulating layer, in outline, as shown partially enlarged in FIG. 2. These kinds of element structures of the switching elements Q and free wheeling diodes D are as introduced in the previously described PTL 2 or the like.

Further, the collector regions C of the switching elements Q1, Q2, and Q3 are each electrically connected to the conductor layer 3a using conductive connection means such as silver paste or solder. Also, the cathode regions K of the free wheeling diodes D1, D2, and D3 are each electrically connected to the conductor layer 3a in the same way.

Meanwhile, the lower arm side switching elements Q4, Q5, and Q6 and free wheeling diodes D4, D5, and D6 are alternately disposed individually on the respective conductor layers 3b and 3c to 3g formed on the right side of and along the conductor layer 3a so as to be insulated and separated from one another. Specifically, the free wheeling diode D4, the switching element Q4, the free wheeling diode D5, the switching element Q5, the free wheeling diode D6, and the switching element Q6 are disposed in this order from the upper side in FIG. 2.

The disposition of the switching elements Q4, Q5, and Q6 and free wheeling diodes D4, D5, and D6 on the respective conductor layers 3b and 3c to 3g is also carried out in the same way as the previously described disposition of the switching elements Q1, Q2, and Q3 and free wheeling diodes D1, D2, and D3. Further, the control circuits IC1, IC2, and IC3 are disposed in this order on and along the ground line conductor layer 3h formed on the left side of the conductor layer 3a.

After that, the switching elements Q1 and Q2 to Q6, the free wheeling diodes D1 and D2 to D6, and the control circuits IC1, IC2, and IC3 are respectively electrically connected using bonding wires 7, which are conductor wires formed of, for example, gold wires or copper wires, so as to establish the relation of connection shown in FIG. 1. Furthermore, the conductor layers 3a, 3b, and 3c to 3g and the plurality of lead frames 5a and 5b to 5j forming the external connection output terminals are also respectively electrically connected using bonding wires 7, which are conductor wires, so as to establish the relation of connection shown in FIG. 1.

Also, in the same way, the control circuits IC1, IC2, and IC3 and the switching elements Q1 and Q2 to Q6 are also electrically connected using bonding wires 7, which are conductor wires, so as to establish the relation of connection shown in FIG. 1. In FIG. 2, a plurality of bonding wires 7, which is conductor wires connecting the control circuits IC1, IC2, and IC3 and the plurality of lead frames 4a and 4b to 4o forming the external connection output terminals, is omitted.

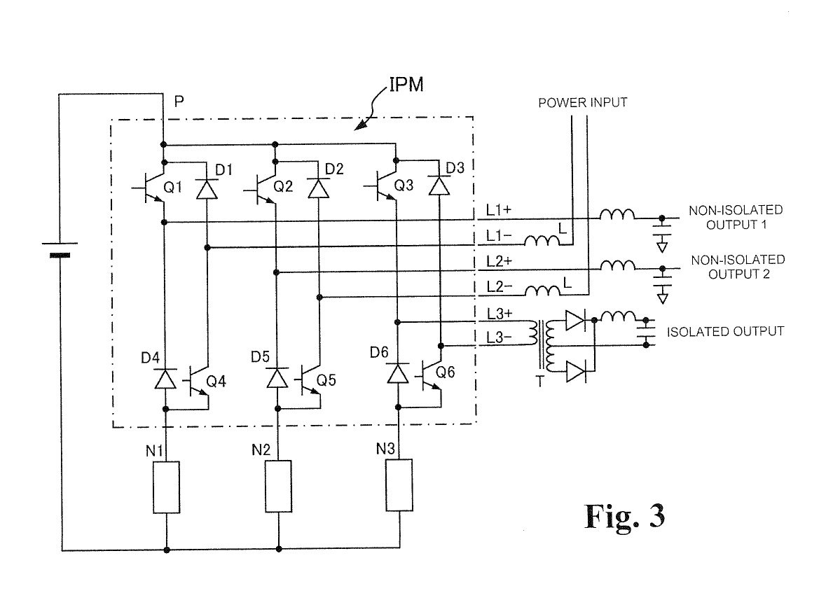

According to the semiconductor module IPM configured in this way, the respective source electrodes (that is, low potential side electrodes) of the upper arm side switching elements Q1, Q2, and Q3 and the respective drain electrodes (that is, high potential side electrodes) of the lower arm side switching elements Q4, Q5, and Q6 are individually led out to the external as the external connection output terminals L1+, L1−, L2+, L2−, L3+, and L3−. Consequently, according to this structure, for example, as shown in FIG. 3, it is possible to interpose an inductance, such as a coil L or a transformer L, between the upper side switching element Q1 (Q2, Q3) and the lower arm side switching element Q4 (Q5, Q6). Therefore, it is possible to easily configure, for example, a double forward converter or an interleaved boost converter.

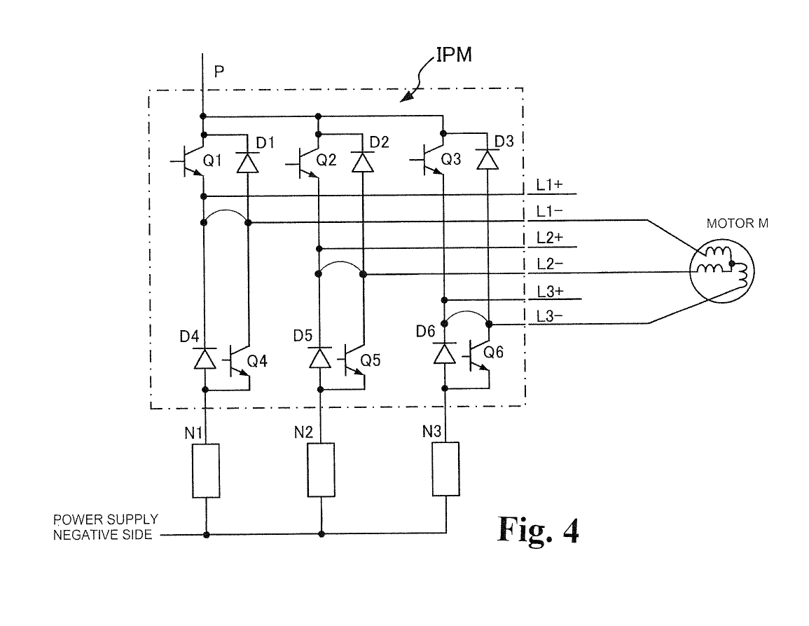

Also, in a case such as driving a three-phase motor M, for example, as shown in FIG. 4, it is only necessary that the upper arm side switching elements Q1 (Q2, Q3) and the lower arm side switching elements Q4 (Q5, Q6) are internally wire connected in pairs in advance inside the semiconductor module IPM, respectively, thus constructing the three sets of half bridge circuits, thereby forming the semiconductor module IPM for exclusive use in driving the three-phase motor M.

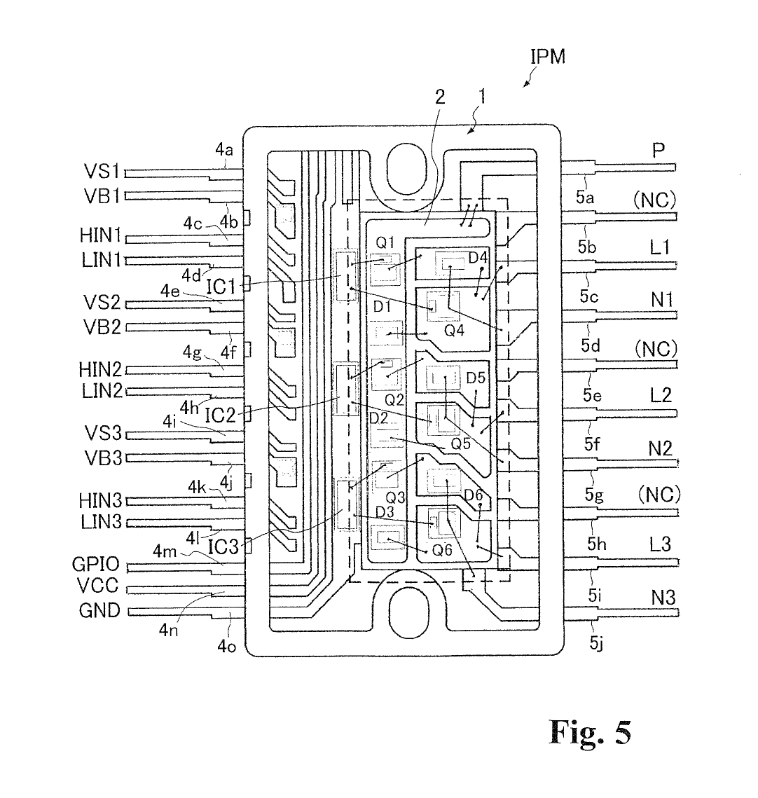

In this case, specifically, for example, as FIG. 5 shows an layout structure of the semiconductor module IPM, it is only necessary to individually electrically connect the respective emitter electrodes E of the lower arm side switching elements Q4 (Q5, Q6) and the respective cathode electrodes K of the lower arm side free wheeling diodes D4 (D5, D6) using the bonding wires 7 which are conductor wires, respectively. It is also possible to individually connect the external connection output terminals L1+, L1−, L2+, L2−, L3+, and L3− in pairs. When in practical operation, however, the heretofore described kind of internal wire connection is preferable from the viewpoint of a current loop flowing through the semiconductor module IPM.

As it is possible, simply by changing the internal wire connection in this way, to form the semiconductor module IPM suitable for driving the three-phase motor M without changing the layout structure itself of the semiconductor module IPM, it is possible to provide the semiconductor module IPM itself with versatility. Consequently, as it is possible to widen the range of utilization (that is, the application) of the semiconductor module IPM, and it is not necessary to develop a semiconductor module complying with various applications, the effect of reducing the cost of the semiconductor module IPM, or the like, is made.

The invention is not limited to the heretofore described embodiment. Herein, a description has been made, for example, for a semiconductor module forming three half bridge circuits, but the invention can also be equally applied when forming a semiconductor module with two sets or four or more sets of half bridge circuits. Also, the invention can also be equally applied when using not only the previously mentioned IGBTs but MOS-FETs as the switching elements Q.

Also, as a matter of course, it is possible to form the whole module main body 1 of the insulating substrate 2 and provide the previously described switching elements Q1 and Q2 to Q6 and free wheeling diodes D4, D5, and D6 on the insulating substrate 2. In this case, it is also possible to integrally form the wiring pattern 3, which is the conductor layer laid on the module main body 1, and the wiring patterns 3 disposed on the insulating substrate 2, including the lead frames 4 and 5. Furthermore, herein, the three control circuits IC1, IC2, and IC3 are provided for driving the switching elements Q1 and Q2 to Q6, but not being limited to this, the respective switching elements Q1 and Q2 to Q6 may be driven by one drive control circuit IC. Apart from this, the invention can be variously modified and implemented without departing from the scope thereof.

### REFERENCE SIGNS LIST

IMP Semiconductor module
Q (Q1, Q2 to Q6) Switching element
D (D1, D2 to D6) Free wheeling diode
1 Module main body
2 Insulating substrate
3 Wiring pattern (conductor layer)
4a, 4b to 4o Lead frame (external connection control terminal)
5a, 5b to 5j Lead frame (external connection output terminal)
7 Bonding wire (conductor wire)

What is claimed is:

1. A semiconductor module comprising:
a plurality of power semiconductor elements forming upper arms and lower arms of a plurality of sets of half bridge circuits;
a plurality of control circuits on/off driving a power semiconductor element having a control terminal in the plurality of power semiconductor elements; and
a power supply terminal and a plurality of control terminals of the control circuits, connected to a plurality of respective external connection control terminals,
wherein low potential side electrodes of the power semiconductor elements forming the respective upper arms of the plurality of sets of half bridge circuits and high potential side electrodes of the power semiconductor elements forming the respective lower arms of the plurality of sets of half bridge circuits are individually connected to a plurality of respective external connection output terminals.

2. The semiconductor module according to claim 1, wherein the high potential side electrodes of the power semiconductor elements forming the respective upper arms of the plurality of sets of half bridge circuits are mutually connected to each other and mounted on an insulating substrate, while the power semiconductor elements forming the respective lower arms of the plurality of sets of half bridge circuits are mounted on the insulating substrate separately from each other.

3. The semiconductor module according to claim 1, wherein the power semiconductor elements forming the respective upper arms of the plurality of sets of half bridge circuits are arranged to align parallel to a long edge of a rectangular module main body arrayed with the plurality of external connection output terminals, and
the power semiconductor elements forming the respective lower arms of the plurality of sets of half bridge circuits are arranged to align parallel to an array direction of the power semiconductor elements forming the respective upper arms.

4. The semiconductor module according to claim 1, wherein the power semiconductor elements are switching elements each formed of an IGBT or MOS-FET having a control electrode and diodes each paired with each respective switching element.

5. The semiconductor module according to claim 4, wherein the switching elements and the diodes are alternately arrayed on each of an upper arm side and a lower arm side of the plurality of sets of half bridge circuits.

6. The semiconductor module according to claim 1, wherein the external connection output terminals individually connected to the low potential side electrodes of the power semiconductor elements forming the respective upper arms of the plurality of sets of half bridge circuits, and the external connection output terminals individually connected to the high potential side electrodes of the power semiconductor elements forming the respective lower arms of the plurality of sets of half bridge circuits, are disposed adjacent to each other in pairs with one pair for each of the plurality of sets of half bridge circuits.
